(19) United States
(12) Patent Application Publication
(10) Pub. No.: US 2020/0344923 A1
(43) Pub. Date: Oct. 29, 2020

(54) SELF-CLOSING ELECTROMAGNETIC INTERFERENCE SHIELDING BAY DOOR

(71) Applicant: Arista Networks, Inc., Santa Clara, CA (US)

(72) Inventors: Daniel Kim, Santa Clara, CA (US); Robert Wilcox, Santa Clara, CA (US); Richard Hibbs, Santa Clara, CA (US)

(21) Appl. No.: 16/392,457

(22) Filed: Apr. 23, 2019

(51) Int. Cl. H05K 9/00

(52) U.S. Cl. CPC H05K 9/0015; H05K 9/0081

(57) ABSTRACT

An enclosure with electromagnetic interference (EMI) shielding door is provided. The enclosure includes an EMI shielding enclosure having an aperture dimensioned to receive an insertable and removable module. The enclosure includes an EMI shielding door attached by a hinge to the EMI shielding enclosure, to close and seal to the aperture with an EMI gasket when the module is removed, and open to receive the module through the aperture when the module is inserted.

### BACKGROUND

In a typical modular chassis, there are multiple bays that can be left unpopulated under a specific product option. Such unfilled bays are problematic because they create large openings where the system cooling air can bypass and EMI (electromagnetic interference) noise can escape. This problem is typically remedied by adding a metallic blank cover to close the opening. But, covers can be misplaced or unavailable, or fall off. Fasteners to secure covers to prevent them from falling off can vibrate loose and cause problems in equipment. Gaps between covers and a chassis can allow airflow and/or EMI noise to escape. It is in this environment that present embodiments arise, to improve modular chassis.

### SUMMARY

In some embodiments, an enclosure with electromagnetic interference (EMI) shielding door is provided. The enclosure includes an EMI shielding enclosure having an aperture dimensioned to receive an insertable and removable module. The enclosure includes an EMI shielding door attached by a hinge to the EMI shielding enclosure, to close and seal to the aperture with an EMI gasket when the module is removed, and open to receive the module through the aperture when the module is inserted.

Other aspects and advantages of the embodiments will become apparent from the following detailed description taken in conjunction with the accompanying drawings which illustrate, by way of example, the principles of the described embodiments.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1A is a cross-section view of a modular chassis with EMI (electromagnetic interference) shielding bay doors for two bays, one populated by a module, the other unpopulated.

FIG. 1B is a cross-section view of a further embodiment of an EMI shielding bay door in part of a modular chassis.

FIG. 2 is a schematic diagram of a modular chassis with EMI shielding bay doors.

FIG. 3 is a cross-section view of an EMI gasket suitable for use in the modular chassis.

FIG. 4 is a schematic diagram of a spring-loaded pin, for an embodiment of a spring-loaded self-closing EMI shielding bay door.

FIG. 5 is a schematic diagram of a further embodiment of a modular chassis with EMI shielding bay doors.

### DETAILED DESCRIPTION

A modular chassis described herein in various embodiments is an EMI (electromagnetic interference) shielding enclosure with one or more EMI shielding bay doors. Each bay of the chassis can receive an insertable and removable module. The chassis and doors use an EMI gasket to seal each door to the chassis. Some embodiments have self-closing doors. The sealed doors prevent EMI noise from escaping and also prevent airflow from escaping to enhance system cooling. With the doors attached by hinges to the chassis, the various embodiments improve upon the typical insert or cover plate that can be misplaced or fall off. With the EMI gasket sealing the door to the chassis, the various embodiments improve upon other chassis with inserts or cover plates and a gap between the chassis and the insert or cover plate, which can allow EMI noise and air flow to escape.

One embodiment has a spring loaded bay door built into a chassis wall or divider. This eliminates the need for a separate, removable blank cover for each field replaceable unit (FRU) bay. One feature described in more detail below is the manner in which the door edges press against fabric-over-foam EMI gaskets on all four sides of the opening as the door closes the opening. It should be appreciated that this feature prevents the EMI noise and air from escaping.

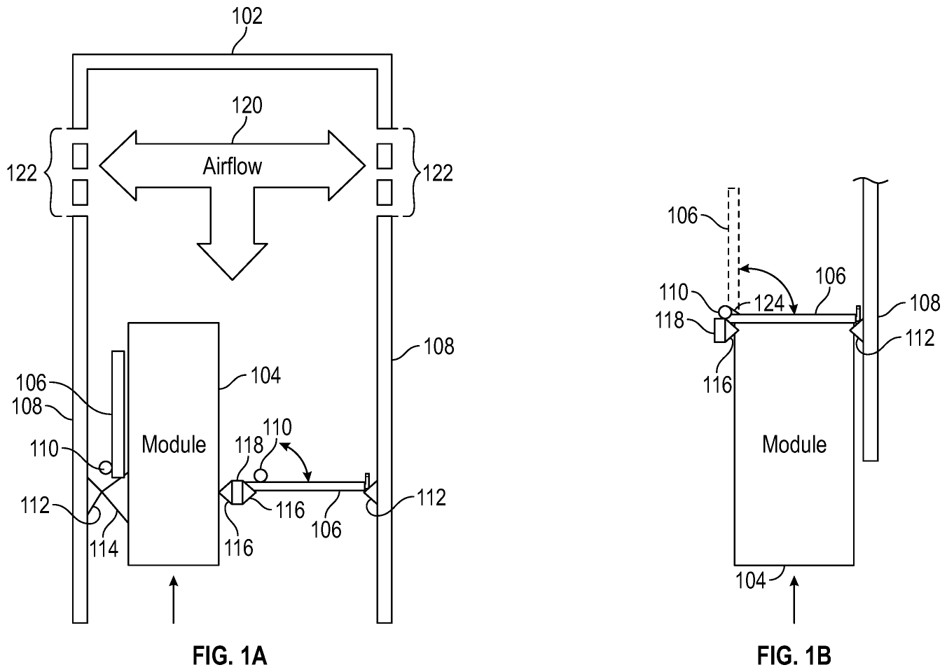

FIG. 1A is a cross-section view of modular chassis 102 with EMI shielding bay doors 106 for two bays, one populated by module 104, the other unpopulated. Chassis 102 forms an enclosure for electronics or other equipment, and can receive one or two modules 104 in this version. Further versions with one bay to receive one module, or more bays to receive more modules, are readily devised in keeping with the teachings herein.

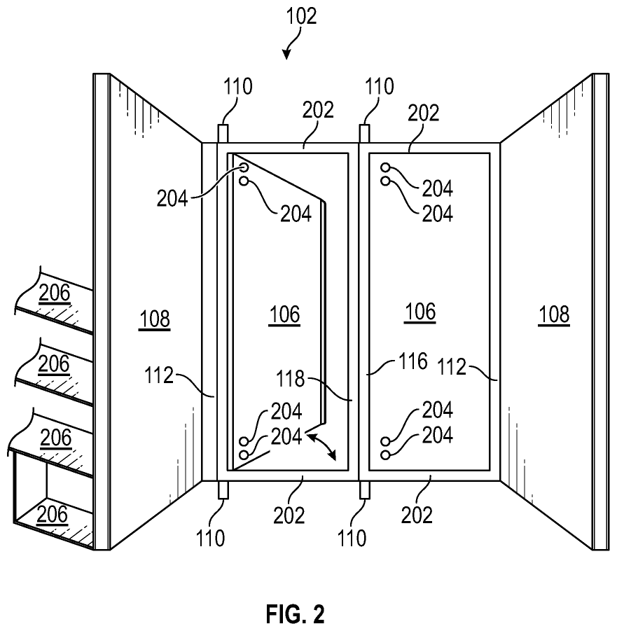

On the right in FIG. 1A, one bay has closed bay door 106 seated to portions of EMI gasket 116, 112. EMI gasket 112, 116 seals bay door 106 to chassis 102, blocking EMI noise and airflow which might otherwise escape through a gap between bay door 106 and chassis wall 108 or interior chassis member 118. Pin 110 attached to one edge of bay door 106, for example by a bracket, fastener, adhesive or other mounting, rotates in an aperture or bearing in chassis 102 and forms a pivot point as a hinge that attaches bay door 106 to chassis 102. The hinge allows bay door 106 to pivot about pin 110 as bay door 106 opens or closes (see two headed curved arrow). Alternatively, pin 110 is attached to chassis 102, and one or more bearings attached to bay door 106 rotate about the pin. The portion of EMI gasket 112 attached to chassis wall 108 near pin 110 seals the edge of bay door 106 nearest pin 110, i.e., the pivoting edge of bay door 106. The portion of EMI gasket 116 attached to interior chassis member 118 seals the edge of bay door 106 farthest from pin 110, i.e., the swinging edge of bay door 106. Other portions of EMI gasket (not shown, but see FIG. 2) seal the top and bottom edges of bay door 106.

On the left in FIG. 1A, one bay has open bay door 106, from insertion of module 104 (see arrow showing direction of insertion). Module 104 pushes bay door 106 open, inward to chassis 102 and bay door 106 un-seats from the portions of EMI gasket 112, 116. Instead, module 104 takes over the role of blocking EMI from the aperture or opening formerly blocked by bay door 106, and seals to the chassis through the portions of EMI gasket 112, 116. In this embodiment, one side of module 104 contacts and thus seals to EMI gasket 116 mounted to interior chassis member 118, another side of module 104 has a further portion of EMI gasket 114 that contacts the portion of EMI gasket 112 mounted to chassis wall 108. Other sides of module 104 contact and seal to further portions of gasket attached to the chassis (not shown, but see FIG. 2).

Airflow 120 through apertures 122 of chassis 102 can be brought about through convection, or force driven with one or more fans (not shown) and could be in any of the arrowhead directions or in other directions within chassis 102 for cooling components as readily envisioned and arranged. Airflow 120 is blocked by EMI gasket 112, 116 sealing closed bay door 106 to chassis 102 and EMI gasket 112, 114, 116 sealing module 104 to chassis 102. It should be readily understood that both airflow 120 and EMI are blocked in configurations with two modules 104 inserted, or both bays left unoccupied, and in various combinations of modules and unoccupied bays in further embodiments of modular chassis with more bays.

FIG. 1B is a cross-section view of a further embodiment of an EMI shielding bay door 106 in part of modular chassis 102. Here, pin 110 is relocated in comparison with the location shown in FIG. 1A, so that bay door 106 swings clear of the portion of EMI gasket 116 and module 104 can contact EMI gasket 116 directly, without need of the portion of EMI gasket 114 attached to module 104 in FIG. 1A. In FIG. 1B, module 104 is depicted pressing against sealed bay door 106, ready to press bay door 106 to open (see dashed line ghost outlining opened bay door 106, and double headed curved arrow showing door travel for opening and closing). Pin 110 is mounted to bay door 106 by bracket 124, supporting the offset of pin 110 relative to bay door 106. Alternatively, bracket 124 has a bearing and pivots about pin 110, which is attached to chassis 102. In the embodiment shown in FIG. 1B, all four edges of rectangular bay door 106, and all four sides of inserted module 104, contact portions of EMI gasket 112, 116 mounted to the chassis, and there is no EMI gasket attached to module 104.

FIG. 2 is a schematic diagram of modular chassis 102 with EMI shielding bay doors 106. For clarity, there are no modules 104 in the drawing. Two walls 108 of the chassis each have a portion of EMI gasket 112 mounted to them. Further portions of EMI gasket 202 are mounted to a floor and ceiling (not shown) of chassis 102, so that the portions EMI gasket 112, 116, 202 completely surround rectangular openings or apertures of chassis 102 to which bay doors 106 seat and seal and through which modules 104 can be inserted. That is, each of four edges of an opening or aperture has a portion of EMI gasket. To the left of leftmost wall 108, shelves 206 of chassis 102 support further equipment (not shown). Pin 110 is attached to bay door 106 by fasteners 204, such as rivets or screws, although other fasteners are readily devised. Each bay door 106 pivots about respective pin(s) 110, opening to receive module 104, or closing upon removal or absence of module 104.

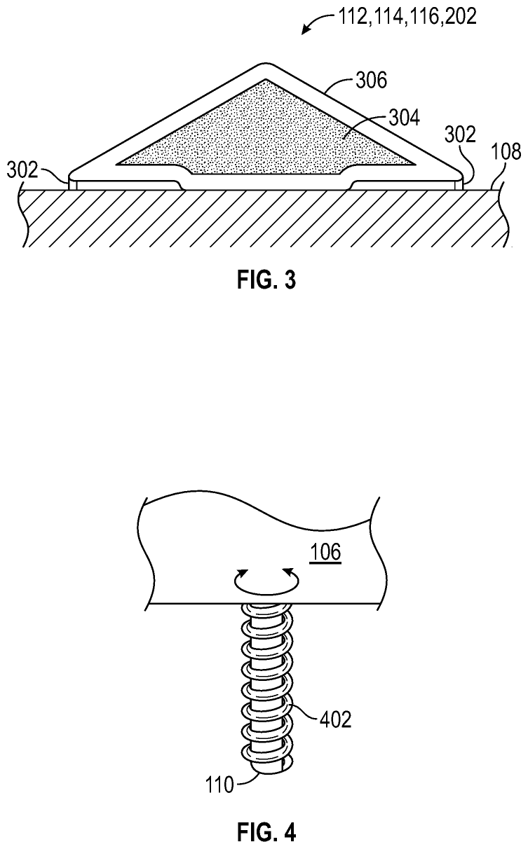

FIG. 3 is a cross-section view of an EMI gasket 112, 114, 116, 202 suitable for use in the modular chassis. EMI gasket 112 has foam core 304, in some versions extruded foam, covered by metallized conductive fabric 306. Adhesive 302, which could be applied as a liquid, or as an adhesive tape or adhesive backed foam, etc., any of which could be conductive, adheres EMI gasket 112 to chassis 102 (e.g., to chassis wall 108 or internal chassis member 118) in various embodiments. In this version, a shallow triangular cross-section of EMI gasket 112 offers surface compliance and sufficient surface area for seating bay door 106 from one direction and module 104 from another direction.

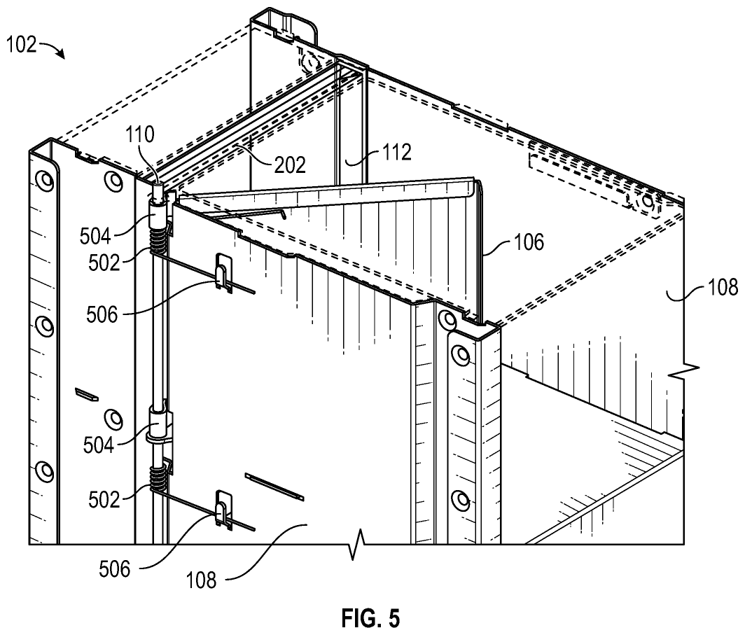

FIG. 4 is a schematic diagram of spring-loaded pin 110, for an embodiment of spring-loaded self-closing EMI shielding bay door 106. Only a cutaway portion of bay door 106 is shown. Spring 402 could be attached at one end to bay door 106 or to pin 110, and at the other end to chassis 102, and biased for self-closing bay door 106 in various embodiments. Self-closing bay door 106 automatically closes and seals to EMI gasket 112, 116, 202 when module 104 is removed or not present. Other types of springs could be used for this functionality in further embodiments.

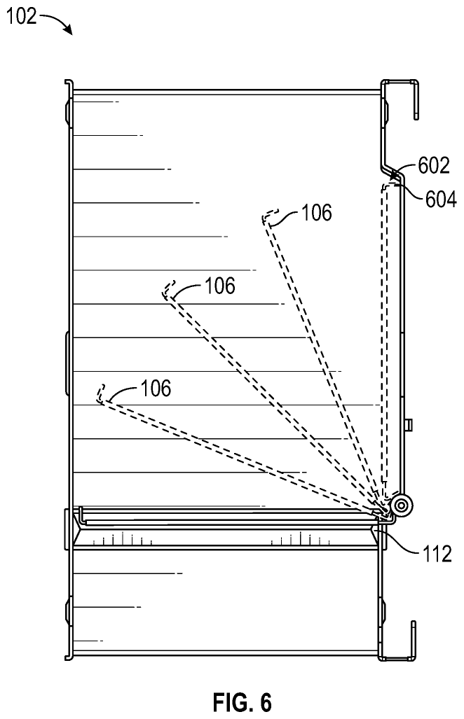

FIG. 5 is a schematic diagram of a further embodiment of modular chassis 102 with EMI shielding bay door 106. One wall 108 of chassis 102 is shaped with a pocket, recess or offset to receive fully opened bay door 106, so that bay door 106 is out of the way of an inserted module 104 (not shown). A hinge attaching bay door 106 to chassis 102 is formed by pin 110, in the form of a long rod, passed through cylindrical bearings 504. Springs 502 have pin 110 passing through them and are attached to chassis wall 108 by fingers 506. Springs 502 press against bay door 106 to self-close bay door 106. EMI gasket 112 is attached to wall 108. EMI gasket 202 is attached to the ceiling (not shown) of chassis 102.

Detailed illustrative embodiments are disclosed herein. However, specific functional details disclosed herein are merely representative for purposes of describing embodiments. Embodiments may, however, be embodied in many alternate forms and should not be construed as limited to only the embodiments set forth herein. It should be appreciated that descriptions of direction and orientation are for convenience of interpretation, and the apparatus is not limited as to orientation with respect to gravity. In other words, the apparatus could be mounted upside down, right side up, diagonally, vertically, horizontally, etc., and the descriptions of direction and orientation are relative to portions of the apparatus itself, and not absolute.

It should be understood that although the terms first, second, etc. may be used herein to describe various steps or calculations, these steps or calculations should not be limited by these terms. These terms are only used to distinguish one step or calculation from another. For example, a first calculation could be termed a second calculation, and, similarly, a second step could be termed a first step, without departing from the scope of this disclosure. As used herein, the term “and/or” and the “/” symbol includes any and all combinations of one or more of the associated listed items.

As used herein, the singular forms “a”, “an” and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof. Therefore, the terminology used herein is for the purpose of describing particular embodiments only and is not intended to be limiting.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Although the method operations were described in a specific order, it should be understood that other operations may be performed in between described operations, described operations may be adjusted so that they occur at slightly different times or the described operations may be distributed in a system which allows the occurrence of the processing operations at various intervals associated with the processing.

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the invention is not to be limited to the details given herein, but may be modified within the scope and equivalents of the appended claims.

1. An enclosure with electromagnetic interference (EMI) shielding door, comprising:
an EMI shielding enclosure having an aperture dimensioned to receive an insertable and removable module; and
an EMI shielding door attached by a hinge to the EMI shielding enclosure, to close and seal to the aperture with an EMI gasket when the module is removed, and open to receive the module through the aperture when the module is inserted.

2. The enclosure with EMI shielding door of claim 1, further comprising:
the EMI shielding door being spring-loaded, biased to close.

3. The enclosure with EMI shielding door of claim 1, further comprising:
the EMI gasket further to seal the module to the aperture when the module is inserted.

4. The enclosure with EMI shielding door of claim 1, wherein the EMI gasket comprises:
extruded foam; and
metallized conductive fabric over the extruded foam.

5. The enclosure with EMI shielding door of claim 4, further comprising:
the aperture having four edges in rectangular arrangement; and
each of the four edges of the aperture having a portion of the EMI gasket.

6. The enclosure with EMI shielding door of claim 4, further comprising:
the aperture having four edges in rectangular arrangement;
each of three of the four edges of the aperture having a portion of the EMI gasket; and
the module having a portion of the EMI gasket on one side.

7. The enclosure with EMI shielding door of claim 4, further comprising:
the hinge having a pin at a first edge of the EMI shielding door; and
the EMI gasket having a first portion attached to a first edge of the aperture to seal to the first edge of the EMI shielding door.

8. The enclosure with EMI shielding door of claim 4, further comprising:
the EMI shielding door further to seal to the aperture to block airflow.

9. A modular chassis, comprising:
a chassis having a plurality of bays defined by chassis walls;
each of the plurality of bays having a self-closing, electromagnetic interference (EMI) shielding, bay door; and
an EMI gasket connected to the chassis and arranged to accept each bay door when closed for each of the plurality of bays.

10. The modular chassis of claim 9, wherein the EMI gasket is arranged so that all edges of each bay door press against the EMI gasket when the bay door is closed.

11. The modular chassis of claim 9, wherein:
each self-closing bay door is to open inward to the modular chassis in response to insertion of a module; and
each self-closing bay door comprises a spring.

12. The modular chassis of claim 9, wherein the EMI gasket comprises fabric over foam.

13. The modular chassis of claim 12, wherein each bay door is to seal to the chassis to prevent air from escaping.

14. The modular chassis of claim 12 wherein the EMI gasket is arranged to seal a gap between the chassis and each bay door.

15-20.

21. An enclosure with electromagnetic interference (EMI) shielding door, comprising:
an EMI shielding enclosure having an aperture dimensioned to receive an insertable and removable module, the EMI shielding enclosure including a sidewall having a recess;
an EMI shielding door attached by a hinge to the EMI shielding enclosure, to close and seal to the aperture with an EMI gasket when the module is removed, and to open to receive the module through the aperture when the module is inserted, the open EMI shielding door positioned in the recess of the sidewall of the EMI shielding enclosure.
